(19) United States
(12) Patent Application Publication
(10) Pub. No.: US 2015/0158511 A1
(43) Pub. Date: Jun. 11, 2015

(54) POINTS MACHINE MONITORING SYSTEM AND METHOD

(71) Applicant: General Electric Company, Schenectady, NY (US)

(72) Inventors: Jeffrey Michael Fries, Grain Valley, MO (US); Joseph Forrest Noffsinger, Grain Valley, MO (US); Richard Lee Lawson, Melbourne, FL (US); Aric Albert Weingartner, Grain Valley, MO (US); Curtis Doyle Mechling, Jacksonville, FL (US); Aaron Richard Mitti, Atlanta, GA (US); Martin Paget, Saint Johns, FL (US); William David Shields, Grain Valley, MO (US)

(21) Appl. No.: 14/529,253

(22) Filed: Oct. 31, 2014

Related U.S. Application Data
(60) Provisional application No. 61/912,075, filed on Dec. 5, 2013.

(51) Int. Cl. B61L 1/20; G01R 31/327; G01R 31/40; B61L 1/02

(52) U.S. Cl. CPC B61L 1/20; B61L 1/02; G01R 31/327; G01R 31/40

(57) ABSTRACT

A method and system for monitoring a points machine obtains operating characteristics of the points machine that are representative of operations of the points machine during a movement event of rails at a switch. A waveform of the operating characteristics is examined to at least one of identify or predict a problem with the operations of the points machine. The waveform is examined by comparing the operating characteristics during the first movement event with at least one of: the operating characteristics obtained during a previous movement event; an expected value of the operating characteristics; or an expected duration of a moving time period during which the first rail is expected to move from or to an unlocked position.

### CROSS-REFERENCE TO RELATED APPLICATIONS

This application claims priority to U.S. Provisional Application No. 61/912,075, which was filed on Dec. 5, 2013, and the entire disclosure of which is incorporated herein by reference.

### FIELD

Embodiments of the inventive subject matter described herein relate to monitoring operations of a machine to identify and/or predict problems with operations of the machine.

### BACKGROUND

Switch points machines are used to operate track switches that enable routing of trains from one track to another. These points machines tend to be relatively heavy mechanical machines moving heavy steel appliances in sometimes extreme conditions. Failure of a points machine can cause total blockage of a railway, since a safe route over a switch may not be established for a train due to the failure. These major events can cause delays to freight and passenger trains, failure to meet schedules that often result in financial penalties, additional costs of train crews and locomotive operations, blockage of highway crossings with impact on the driving public, and reputation loss to customers, among other problems.

Points machines are lubricated, adjusted, and otherwise maintained on a periodic basis, but given the often remote location of these machines, the maintenance forces may be unaware of the impact of number of operations, weather, and changing ground surface conditions affecting the track layout. Misalignment of the track sleepers can create binding effects requiring additional force to move the rails in a switch over time.

### BRIEF DESCRIPTION

In one embodiment, a method (e.g., for monitoring a points machine) includes obtaining operating characteristics of a points machine from a monitor operatively connected with the points machine. The operating characteristics are representative of operations of the points machine during a first movement event of rails at a switch. The first movement event moves at least a first rail toward or away from a second rail in order to change a path traveled by a vehicle traveling over the switch. The method also can include examining a waveform of the operating characteristics with a processor device in order to at least one of identify or predict a problem with the operations of the points machine. The waveform is examined by comparing the operating characteristics during the first movement event with at least one of the operating characteristics obtained during a previous, second movement event, an expected value of the operating characteristics during a first moving time period in which the at least a first rail is moved toward or away from the second rail by the points machine during the first movement event, and/or an expected duration of a second moving time period during which the at least a first rail is expected to at least one of move from an unlocked position away from the second rail to a locked position at or near the second rail or to move from the locked position to the unlocked position.

In another embodiment, a system (e.g., a points machine monitoring system) includes a monitor and a processor device. The monitor is configured to measure operating characteristics of a points machine. The operating characteristics are representative of operations of the points machine during a first movement event of rails at a switch. The first movement event moves at least a first rail toward or away from a second rail in order to change a path traveled by a vehicle traveling over the switch. The processor device is configured to examine a waveform of the operating characteristics in order to at least one of identify or predict a problem with the operations of the points machine. The processor device also is configured to examine the waveform by comparing the operating characteristics during the first movement event with at least one of the operating characteristics obtained during a previous, second movement event, an expected value of the operating characteristics during a first moving time period in which the at least a first rail is moved toward or away from the second rail by the points machine during the first movement event, and/or an expected duration of a second moving time period during which the at least a first rail is expected to at least one of move from an unlocked position away from the second rail to a locked position at or near the second rail or to move from the locked position to the unlocked position.

In another embodiment, another method (e.g., for monitoring a points machine) includes measuring operating characteristics of a points machine when the points machine is activated to attempt to move first and second rails of a switch toward or away from a third rail to change a path traversed by a vehicle traveling over the switch. The operating characteristics include at least one of an electric current supplied to a motor of the points machine that generates movement to move the first and second rails, a fluid pressure generated by the points machine to move the first and second rails, and/or a rate of fluid flow generated by the points machine to move the first and second rails. The method also includes comparing the operating characteristics of the points machine with historical values of the operating characteristics that previously were obtained during one or more previous attempts by the points machine to move the first and second rails of the switch, the operating characteristics compared with the historical values in order to identify one or more differences. The method also includes at least one of identifying or predicting a problem with the points machine based on the one or more differences that are identified, the problem including at least one of a deterioration of a lubricant on switch plates of the points machine, a misalignment of at least one of the first rail or the second rail, at least one of the first rail or second rail being stuck in position, a clutch of the points machine slipping, and/or a foreign object stuck between at least one of the first rail or the second rail and one or more other rails.

### BRIEF DESCRIPTION OF THE DRAWINGS

Reference is now made briefly to the accompanying drawings, in which:

FIG. 1 is a schematic diagram of a points machine monitoring system in accordance with one embodiment of the inventive subject matter described herein;

FIG. 2 illustrates one example of a waveform of operating characteristics of the points machine shown in FIG. 1 during operation of the points machine to move rails shown in FIG. 1;

FIG. 3 illustrates an example of waveforms of the operating characteristics of the points machine shown in FIG. 1 during operation of the points machine to move the rails when lubricant on switch plates deteriorates or decreases, or when the vertical alignment of the rails changes with respect to the points machine;

FIG. 4 illustrates an example of another waveform of the operating characteristics of the points machine shown in FIG. 1 during operation of the points machine to move the rails when one or more of the rails engages a foreign object;

FIG. 5 illustrates an example of another waveform of the operating characteristics of the points machine shown in FIG. 1 during operation of the points machine to move the rails when the rails are stuck or otherwise immovable by the points machine;

FIG. 6 illustrates an example of another waveform of the operating characteristics of the points machine shown in FIG. 1 during operation of the points machine to move the rails when a clutch of the points machine slips; and

FIG. 7 illustrates a flowchart of a method for monitoring a points machine in accordance with one embodiment of the inventive subject matter.

### DETAILED DESCRIPTION

One or more embodiments of the inventive subject matter described herein provide systems and methods that can monitor energy flow to a railway points machine in order to monitor overall health of the machine itself. The energy flow can be monitored in high resolution, such as by examining the waveform shape of the energy (e.g., electric current) and timing of various features-of-interest in the waveform shape to determine certain heath characteristics of the points machine, the railway track section to which the points machine is connected, and the like. For example, these health characteristics that are determined can represent the overall health of the points machine, certain physical properties of the railway track section that the points machine operates to control (e.g., such as vertical alignment of the railway track section with the points machine), the lubrication state of the rails-to-tie plate interface at the points machine, and the like.

One embodiment described herein includes a monitoring system that measures voltage and/or current supplied to an electrical machine, such as a points machine, to monitor the health and/or status of the machine. The monitoring system can additionally or alternatively measure fluid pressure and/or flow for air powered and/or hydraulic powered machines, such as a hydraulic or air powered points machine. The system can capture, record, and/or analyze the data representative of the electric currents supplied to the points machine or representative of the fluid pressure or air flow of the points machine, and based on this analysis, automatically communicate signals to one or more other locations in order to request examination, maintenance, or repair of the points machine by one or more human operators or other systems.

In one aspect, the analysis of the data may involve calculating deviations of the electric current, fluid pressure, and/or air flow from designated values (e.g., values indicative of healthy or “ideal” performance) to determine when the data indicates that the points machine may need maintenance or repair. As another example, this analysis may include use of a comparative lookup in a preset table of values (e.g., comparing the actual data with data designated in a table to determine if the actual data exceeds, falls below, or otherwise is outside of a designated range in the table and, as a result, the points machine may need maintenance or repair. As another example, the analysis of the data could involve use of a learning database that compares historical values of the electric current, fluid pressure, and/or air flow to currently or recently obtained values for a points machine that is under examination. The learning database may include data values of the same and/or other points machines (with this data being updated over time) that were found to need repair or maintenance. Based on this comparison, the points machine under examination may be identified as a machine that may need repair or maintenance. Additionally or alternatively, the analysis may involve examining trends in historical values of the electric current, fluid pressure, and/or air flow in the same or other points machines that previously were later identified as requiring repair or maintenance. These historical trends in the data values can be compared to trends in actual values of the electric current, fluid pressure, air flow, or the like, or a points machine under examination, to determine if the trends in actual values match one or more of the historical trends. If there is a match, then the repair or maintenance that previously was performed for the points machine associated with the historical trend that matched the trend in the actual values of the points machine under examination (or that matched the trend in the actual values more than one or more, or all, of the other historical trends) may be performed on the points machine under examination.

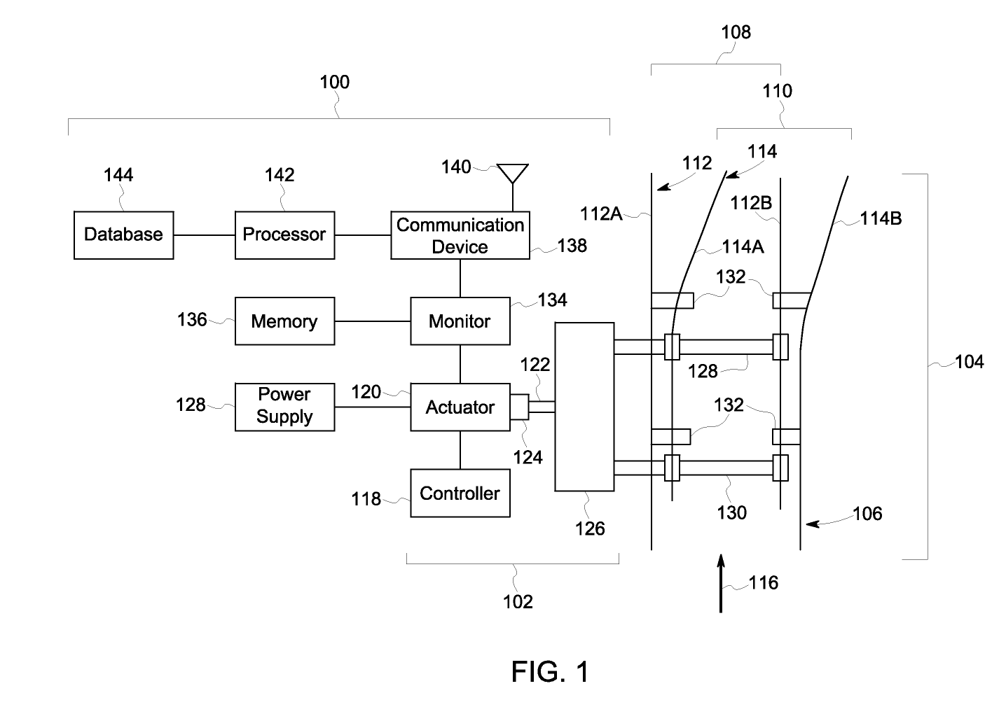

FIG. 1 is a schematic diagram of a points machine monitoring system 100 in accordance with one embodiment of the inventive subject matter described herein. The monitoring system 100 is operably connected with a points machine 102 that is mechanically coupled with a switch 104 of a route 106. By “operably connected,” it is meant that the monitoring system 100 is connected with the points machine 102 by one or more wired and/or wireless connections to measure operational characteristics of the points machine 102, as described below. The route 106 is illustrated as a track on which rail vehicles travel, but alternatively could be another type of path on which a vehicle or vehicle system travels. The switch 104 represents a location along the route 106 where two different paths intersect. In the illustrated example, first and second paths 108, 110 intersect at the switch 104.

The paths 108, 110 of the route 106 are defined by parallel sets of rails 112, 114 (e.g., rails 112A, 112B, 114A, 114B). The path 108 shown in FIG. 1 is defined by the parallel rails 112A, 112B and the path 110 is defined by the parallel rails 114A, 114B. In order to change which of the paths 108, 110 that a vehicle travels on when the vehicle travels over the switch 104, the points machine 102 can be activated to move the rails 114A, 112B relative to the rails 112A, 114B. For example, if a vehicle is traveling on the rails 112A, 112B along the path 108 in the direction indicated by arrow 116 in FIG. 1, then the points machine 102 may be activated to move the rail 114A toward the rail 112A and to move the rail 112B away from the rail 114B. The switch 104 can include switch plates 132 that provide surfaces on which the rails 114A, 112B slide or otherwise move. The switch plates 132 may be lubricated with oil or another lubricant to reduce the force needed to move the rails 114A, 112B. The rail 114A may be moved sufficiently far that the rail 114A contacts the rail 112A. When the vehicle reaches the switch 104, the vehicle moves from traveling on the rails 112A, 112B of the path 108 to traveling on the rails 114A, 114B of the path 110.

On the other hand, if the vehicle is traveling on the rails 112A, 112B along the path 108 in the direction indicated by arrow 116 in FIG. 1 and the rail 114A is contacting the rail 112A, the points machine 102 may be activated to move the rail 114A away from the rail 112A and to move the rail 112B toward the rail 114B. When the vehicle reaches the switch 104, the vehicle continues along the rails 112A, 11B through the switch 104 and does not move from traveling on the path 108 to traveling on the rails 114A, 114B of the path 110.

In order to move the rails 114A, 112B, the points machine 102 includes a controller 118 that determines when and which direction to activate an actuator 120. The controller 118 may include or represent one or more hardware circuits or circuitry that include and/or are connected with one or more computer processors, hardwired logic, or other electronic logic-based devices. The actuator 120 can include an electronic motor that is turned on or off by the controller 118 to rotate a shaft 122 in a selected direction. A power supply 128, such as a utility power grid, battery, capacitor, flywheel, fuel cell, or the like, provides electric energy (e.g., current) to the actuator 120 to activate the actuator 120. A clutch 124 may be coupled to the actuator 120 and the shaft 122 to allow the actuator 120 to rotate without rotating the shaft 122. Rotation of the shaft 122 is translated into lateral movement of the rails 114A, 112B by a translation assembly 126. The translation assembly 126 may include one or more gears, pinions, and the like, that convert rotation of the shaft 122 by the actuator 120 into lateral movement of pistons 128, 130. As shown in FIG. 1, the pistons 128, 130 are connected with the rails 114A, 112B such that rotation of the shaft 122 in one direction by the actuator 120 causes the rails 114A, 112B to move to the right in the perspective of FIG. 1 while rotation of the shaft 122 in the opposite direction by the actuator 120 causes the rails 114A, 112B to move in the opposite (e.g., left) direction.

Alternatively, the points machine 102 may be a pneumatic machine. For example, the actuator 120 may include a pump that is controlled by the controller 118 to force hydraulic fluid, air, or another fluid, into the assembly 126 (such as through a conduit represented by 122). The assembly 126 can convert pressure, flow rate, or the like, of the fluid into lateral movement of the pistons 128, 130, similar to as described above.

The monitoring system 100 examines operating characteristics of the points machine 102 in order to identify faults or failures in the points machine 102 and/or to predict when maintenance or repair of the points machine 102 may be needed. The monitoring system 100 includes an operational monitor 134 (e.g., “monitor” in FIG. 1) that measures the operating characteristics of the points machine 102. If the points machine 102 uses an electronic motor to move the rails 114A, 112B, then the operational monitor 134 can measure one or more characteristics of the electric current (e.g., amps, volts, frequency, or the like) that is supplied to the actuator 120 to move the rails 114A, 112B as the operating or operational characteristics. For example, the monitor 134 can include one or more hardware circuits or circuitry that include and/or are connected with an electronic sensor, such as an amp meter, voltmeter, or the like. If the points machine 102 uses pneumatic pressure to move the rails 114A, 112B, then the operational monitor 134 can measure the pressure of the fluid, the rate at which the fluid flows in the points machine 102, or the like, as the operating or operational characteristics. For example, the monitor 134 can include one or more hardware circuits or circuitry that include and/or are connected with a pressure sensor and/or flow rate sensor.

The operational monitor 134 can record the operating characteristics of the points machine 102 in a memory 136. The memory 136 of the monitoring system 100 includes one or more devices that can store the operating characteristics measured by the monitor 134. For example, the memory can include one or more computer hard drives, flash drives, magnetic tapes, optical discs, or the like.

A communication device 138 of the monitoring system includes transceiver hardware and/or circuitry that includes or is connected with one or more transceiver devices 140 (e.g., an antenna, modem, or the like) that communicate signals with a processor device 142 (e.g., “processor” in FIG. 1). The communication device 138 may communicate the signals with the processor device 142 wirelessly and/or over one or more wired connections. The processor device 142 includes or represents one or more hardware circuits or circuitry that includes and/or is connected with one or more computer processors, controllers, or other electronic logic-based devices. The processor device 142 may include or be connected with a communication device similar to the communication device 138 in order to receive the signals from the communication device 138. The processor device 142 may be located near the monitor 134 or may be located remote from the monitor 134, such as several miles or kilometers away.

The monitor 134 can communicate the operating characteristics of the points machine 102 to the processor device 142 via the communication device 140 as the operating characteristics are measured by the monitor 134. Additionally or alternatively, the monitor 134 may store several operating characteristics of the points machine 102 in the memory 136 and send the operating characteristics of the points machine 102 to the processor device 142 periodically, when requested by the processor device 142, or the like.

The processor device 142 is communicatively connected with a database 144 that may store historical values of operating characteristics of the points machine 102 and/or one or more other points machines. The database 144 can be similar to the memory 136 and can store data representative of operational characteristics from several points machines. The database 144 may store faults or failures that previously were identified for these points machines, along with the operating characteristics and/or trends in the operating characteristics associated with the previously identified faults or failures.

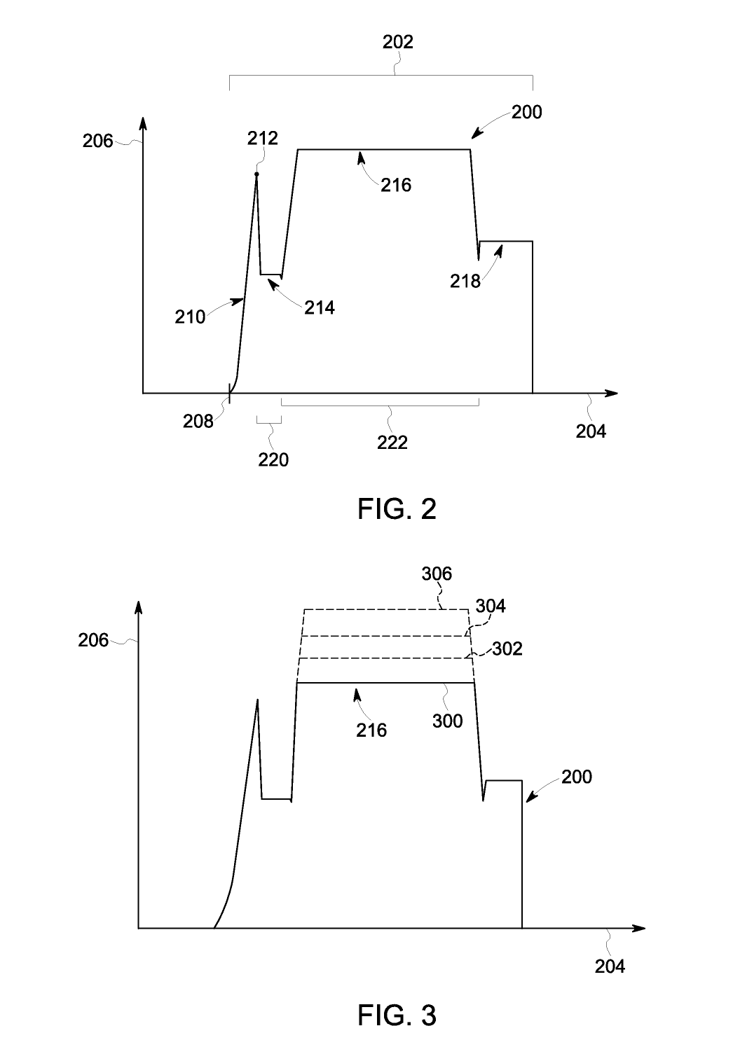

FIG. 2 illustrates one example of a waveform 202 of operating characteristics 200 of the points machine 102 (shown in FIG. 1) during operation of the points machine 102 to move the rails 114A, 112B (shown in FIG. 1). The operating characteristics 200 are shown alongside a horizontal axis 204 representative of time and a vertical axis 206 representative of magnitudes of the operating characteristics 200. As described above, the operating characteristics 200 can represent the electric current (e.g., in terms of amps, voltage, power, or the like) supplied to the actuator 120 (shown in FIG. 1) or the fluid pressure, flow rate, or the like, generated by the actuator 120 to move the rails 114A, 112B.

At a first time 208, the controller 118 (shown in FIG. 1) of the points machine 102 directs the actuator 120 to begin moving the rails 114A, 112B. The operating characteristics 200 may rapidly increase following this first time 208, as represented by a sharp increase 210 in the electric current demanded by the motor of the actuator 120 or the fluid pressure, flow rate, or the like, initially generated by the actuator 120 to move the rails 114A, 112B. The operating characteristics 200 sharply increase to a first peak 212, followed by a relatively rapid decrease to a first plateau 214 in the waveform 202. During an unlocking time period 220 during which the first plateau 214 occurs, the rails 114A, 112B are unlocked from a stationary position, which also may be referred to as a locked position. For example, if the rail 114A is initially in a position against the rail 112A, then the first plateau 214 may represent the operating characteristics 200 of the points machine 102 when the rail 114A is unlocked (e.g., separated) from the rail 112A. Alternatively, if the rail 112B is initially in a position against the rail 114B, then the first plateau 214 may represent the operating characteristics 200 of the points machine 102 when the rail 112B is unlocked (e.g., separated) from the rail 114B.

Once the rail 114A and/or 112B is unlocked from the corresponding rail 112A or 114B, the operating characteristics 200 may again rapidly increase to a second plateau 216. The second plateau 216 represents the amount of electric current demanded by the actuator 120, the fluid pressure generated by the actuator 120, the flow rate generated by the actuator 120, or the like, that is used to move the rails 114A, 112B across the switch plates 132 (shown in FIG. 1). During a moving time period 222 during which the operating characteristics 200 are in the second plateau 216, the rails 114A, 112B are being moved across the switch plates 132 toward or away from the corresponding rails 112A, 114B.

Once the rails 114A, 112B reach final locations, the operating characteristics 200 rapidly decrease to a third plateau 218. For example, once the rail 114A is moved to be engaged with (or relatively close to) the rail 112A, the operating characteristics 200 may decrease to the third plateau 218. As another example, once the rail 112B is moved to be engaged with (or relatively close to) the rail 114B, the operating characteristics 200 may decrease to the third plateau 218. During the time period over which the operating characteristics 200 are in the third plateau 218, the rail 114A or 112B is pressed into a locking engagement with the corresponding rail 112A or 114B. Once the rail 114A or 112B is locked against the corresponding rail 112A or 114B, the operating characteristics 200 decrease. As shown in FIG. 2, the operating characteristics 200 may decrease to zero once the rail 114A or 112B is locked against the corresponding rail 112A or 114B.

FIG. 3 illustrates an example of waveforms 300, 302, 304, 306 of the operating characteristics 200 of the points machine 102 (shown in FIG. 1) during operation of the points machine 102 to move the rails 114A, 112B (shown in FIG. 1) when lubricant on the switch plates 132 (shown in FIG. 1) deteriorates or decreases, or when the vertical alignment of the rails 112, 114 (shown in FIG. 1) changes with respect to the points machine 102. The waveforms 300, 302, 304, 306, 308 can represent the operating characteristics 200 of the points machine 102 during different movements of the rails 114A, 112B. The processor device 142 (shown in FIG. 1) may examine the operating characteristics 200 of the points machine 102 over time and several movements of the rails 114A, 112B and identify an upward trend in the second plateau 216 of the operating characteristics 200.

The first waveform 300 can represent the operating characteristics 200 during a first movement event that involves moving the rails 114A, 112B toward or away from the rail 112A or 114B, the second waveform 302 can represent the operating characteristics 200 during a later or subsequent second movement event involving moving the rails 114A, 112B toward or away from the rail 112A or 114B, and so on for the third and fourth waveforms 304, 306. As shown in FIG. 3, the operating characteristics 200 in the second plateaus 216 of the waveforms 300, 302, 304, 306 gradually increase in magnitude over time.

The processor device 142 can identify this increasing trend in the operating characteristics 200 during the second plateau 216 and determine that the amount of energy needed for the points machine 102 to move the rails 114A, 112B is increasing over time. This increased amount of energy may be due to lubricant on the switch plates 132 deteriorating, the rails 112, 114 moving out of alignment with respect to the points machine 102 (e.g., moving vertically upward or downward with respect to the points machine 102), or that one or more other causes are increasing the amount of energy needed to move the rails 114A, 112B. In response to making this determination, the processor device 142 may communicate (e.g., transmit and/or broadcast) a signal to a remote location to request that an operator travel to the points machine 102 to further examine or repair the points machine 102. For example, this signal may request that additional lubricant be added to the switch plates 132, that the switch plates 132 be cleaned, that the vertical alignment of the rails 112, 114 relative to the points machine 102 be examined and/or corrected, or the like, so that the energy needed to move the rails 114A, 112B decreases.

The processor device 142 can predict when the points machine 102 will fail and be unable to move the rails 114A, 112B using the trend in the operating characteristics. For example, as the operating characteristics during the moving time period continue to increase over several movement events of the rails 114A, 112B, the processor device 142 can predict a remaining time to failure of the points machine 102. The remaining time to failure can be identified as occurring sooner for larger increasing trends in these operating conditions, or as occurring later for smaller increasing trends in the operating conditions.

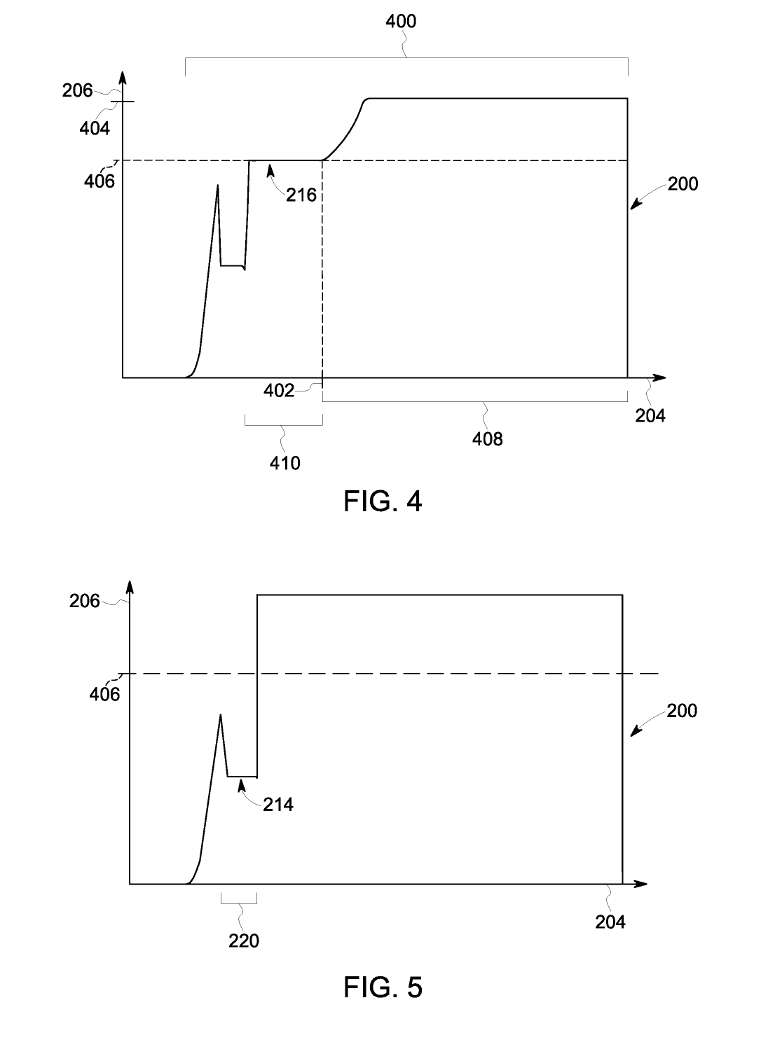

FIG. 4 illustrates an example of another waveform 400 of the operating characteristics 200 of the points machine 102 (shown in FIG. 1) during operation of the points machine 102 to move the rails 114A, 112B (shown in FIG. 1) when one or more of the rails 114A, 112B engages a foreign object. As shown in FIG. 4, the waveform 400 of the operating characteristics 200 is similar to the waveform 202 shown in FIG. 2 during normal operation of the points machine 102 up to the second plateau 216 of the operating characteristics 200.

In the illustrated example, one or more of the rails 114A, 112B contacts a foreign object on the route 106 (shown in FIG. 1) while being moved by the points machine 102 and is prevented from being moved and locked into position (e.g., against the corresponding rail 112A or 114B). For example, the rail 114A may contact a portion of ballast material on which the rails 112, 114 are disposed such that the portion of ballast material is stuck between the rail 114A and the rail 112A when the points machine 102 tries to move the rail 114A toward and against the rail 112A. This portion of ballast material can prevent the rail 114A from contacting the rail 112A.

The processor device 142 can examine the operating characteristics 200 shown in FIG. 4 during such a movement of the rails and determine that one or more of the rails 114A, 112B are prevented from being moved into the locked position against the corresponding rail 112A, 114B. The waveform 400 of the operating characteristics 200 may be similar to the operating characteristics 200 in the waveform 300 shown in FIG. 3 up until a contact time 402. At the contact time 402, the operating characteristics 200 increase from a value 406 of the operating characteristics 200 in the second plateau 216. The operating characteristics 200 may increase to an upper limit or threshold 404 of the actuator 120 (shown in FIG. 1), such as a maximum output (e.g., current, pressure, air flow, or the like) that the actuator 120 is capable of producing, or another value.

The processor device 142 may determine that this increase of the operating characteristics 200 above the value 406 of the second plateau 216 indicates that the actuator 120 is demanding increased electric current without the electric current being used to move the rails 114A, 112B. Alternatively, the processor device 142 may determine that this increase of the operating characteristics 200 above the value 406 second plateau 216 indicates that the actuator 120 is generating increased fluid pressure, flow, or the like, without the pressure, flow, or the like, being used to move the rails 114A, 112B. The processor device 142 can be programmed to identify such an increase in the operating characteristics 200 to be indicative of a foreign object preventing the rails 114A, 112B from moving to the locked position against at least one of the rails 112A or 114B.

In one aspect, the processor device 142 may make this determination by examining one or more historical values or trends of previously measured operating characteristics 200 stored in the database 144 for the points machine 102 and/or one or more points machines. These historical values or trends may define typical or expected values of the operating characteristics 200 in the second plateau 216. For example, the average, median, or other measurement of several operating characteristics 200 of one or more points machines 102 may be calculated as the value 406 of the operating characteristics 200 in the second plateau 216. This value may be referred to as an expected value of the operating characteristics 200 during movement of the rails 114A, 112B. The processor device 142 can compare actual values of the operating characteristics 200 for the points machine 102 that is attempting to move the rails 114A, 112B with the expected value 406 to determine if the actual operating characteristics 200 of the points machine 102 are increasing beyond the expected value 406. If the operating characteristics 200 increase above the expected value 406 for at least a designated period of time, the processor device 142 may identify a foreign object between the rails 114A, 112B and one or more of the rails 112A, 114B. Additionally or alternatively, the processor device 142 may determine that there is a foreign object between the rails 114A, 112B and one or more of the rails 112A, 114B when the actual operating characteristics 200 of the points machine 102 are relatively level or flat during movement of the rails 114A, 112B (e.g., during the time period 410) and then increase above this relatively level or flat level, such as is shown in FIG. 4 following the contact time 402.

The operating characteristics 200 may remain above the expected value 406 for a designated period of time 408. This period of time 408 may be a limit of the actuator 120 that, when exceeded, causes the actuator 120 to stop demanding current and/or generating fluid pressure, flow, or the like, to move the rails 114A, 112B. For example, the period of time 408 can be a limit that is established to prevent the motor or pump in the actuator 120 from burning out. If the operating characteristics 200 remain above the expected value 406 for at least the period of time 408, then the actuator 120 may turn off or otherwise stop attempting to move the rails 114B, 112A. As a result, the operating characteristics 200 decrease, as shown in FIG. 4.

FIG. 5 illustrates an example of another waveform 500 of the operating characteristics 200 of the points machine 102 (shown in FIG. 1) during operation of the points machine 102 to move the rails 114A, 112B (shown in FIG. 1) when the rails 114A, 112B are stuck or otherwise immovable by the points machine 102. The waveform 500 is similar to the waveform 400 shown in FIG. 4, except that there is no delayed time period 410 between the unlocking of the rails 114A, 112B (e.g., the first plateau 214) and the increase in the operating characteristics 200 above the expected value 406. Instead, the operating characteristics 200 rapidly increase above the expected value 406, such as to an upper limit of the actuator 120 or another value. The operating characteristics 200 do not remain at or near the expected value 406 of the second plateau 216, as the operating characteristics 200 may do when the clutch 124 slips (as one example).

The processor device 142 can identify this relatively rapid increase of the operating characteristics 200 and determine that one or more of the rails 114A, 112B is stuck in position. For example, the processor device 142 may associate the waveform 400 shown in FIG. 4 as being indicative of a foreign object between the rail 114A and the rail 112A or between the rail 112B and the rail 114B because the operating characteristics 200 being at or near the expected value 406 for the delayed time period 410 may indicate that the movement generated by the actuator 120 at least partially moved the rails 114A, 112B before contacting the foreign object. On the other hand, the rapid increase of the operating characteristics 200 above the expected value 406 in the waveform 500 may be identified by the processor device 142 as being indicative of the actuator 120 being unable to move the rails 114A, 112B. The current demanded by the actuator 120 may increase to the upper limit of the actuator 120 because of the rails 114A, 112B potentially being stuck before being moved from the locked position against another corresponding rail 112A or 114B.

The processor device 142 can identify the rails 114A, 112B as potentially being stuck based on this rapid increase following the unlocking plateau 214 and may communicate a signal to a remote location to request inspection of the points machine 102. This signal can indicate that the rails 114A, 112B may be frozen or otherwise unable to be moved. In one aspect, the signal generated by the processor device 142 can recommend inspection of a heating device at or near the points machine 102 that is to prevent the rails 114A, 112B from being frozen in position.

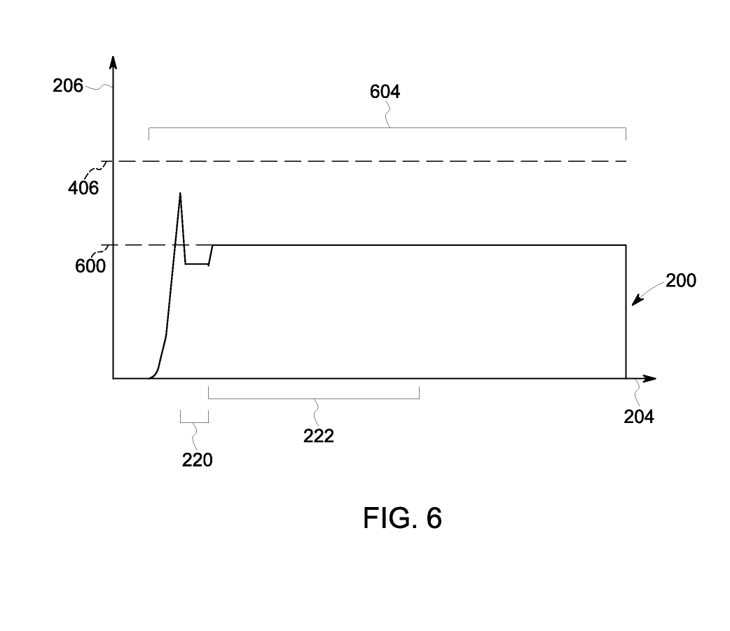

FIG. 6 illustrates an example of another waveform 604 of the operating characteristics 200 of the points machine 102 (shown in FIG. 1) during operation of the points machine 102 to move the rails 114A, 112B (shown in FIG. 1) when the clutch 124 (shown in FIG. 1) of the points machine 102 slips. As shown in FIG. 6, the waveform 604 of the operating characteristics 200 is similar to the waveform 202 shown in FIG. 2 during normal operation of the points machine 102 up to and including the first plateau 214 representative of unlocking the rail 114A from the rail 112A or the rail 112B from the rail 114B.

Following the unlocking time period 220, the operating characteristics 200 increase again, but do not increase up to the expected level 406 associated with moving the rails 114A, 112B. As described above, the level 406 may be obtained from historical values of the operating characteristics 200 for the points machine 102 and/or one or more other points machines. The processor device 142 may determine that the clutch 124 of the points machine 102 has slipped such that rotation of the actuator 120 (e.g., the motor) is not rotating the shaft 122 and, as a result, the rails 114A, 112B are not being moved. The processor device 142 can make this determination when the operating characteristics 200 do not increase to the expected level 406 for an extended time period. For example, when the operating characteristics 200 remain below the expected level for a time period that follows the unlocking time period 220 and that is longer than the moving time period 222, the processor device 142 may determine that the clutch 124 has slipped. Similar to the expected value 406, the moving time period 222 may be an expected moving time period 222 that is calculated from historical values of the moving time periods for the same and/or different points machines 102 that are stored in the database 144. The processor device 142 can compare the time period during which the actual operating characteristics 200 of the points machine 102 under examination remain less than the expected value 406 with the expected moving time period 222. If the time period during which the actual operating characteristics 200 of the points machine 102 under examination remain less than the expected value 406 exceeds the expected moving time period 222, then the processor device 142 may identify the points machine 102 as having a clutch 124 that has slipped. In one aspect, the processor device 142 may automatically generate and communicate a signal to a remote location to request that an operator travel to the points machine 102 and examine and/or repair the points machine 102.

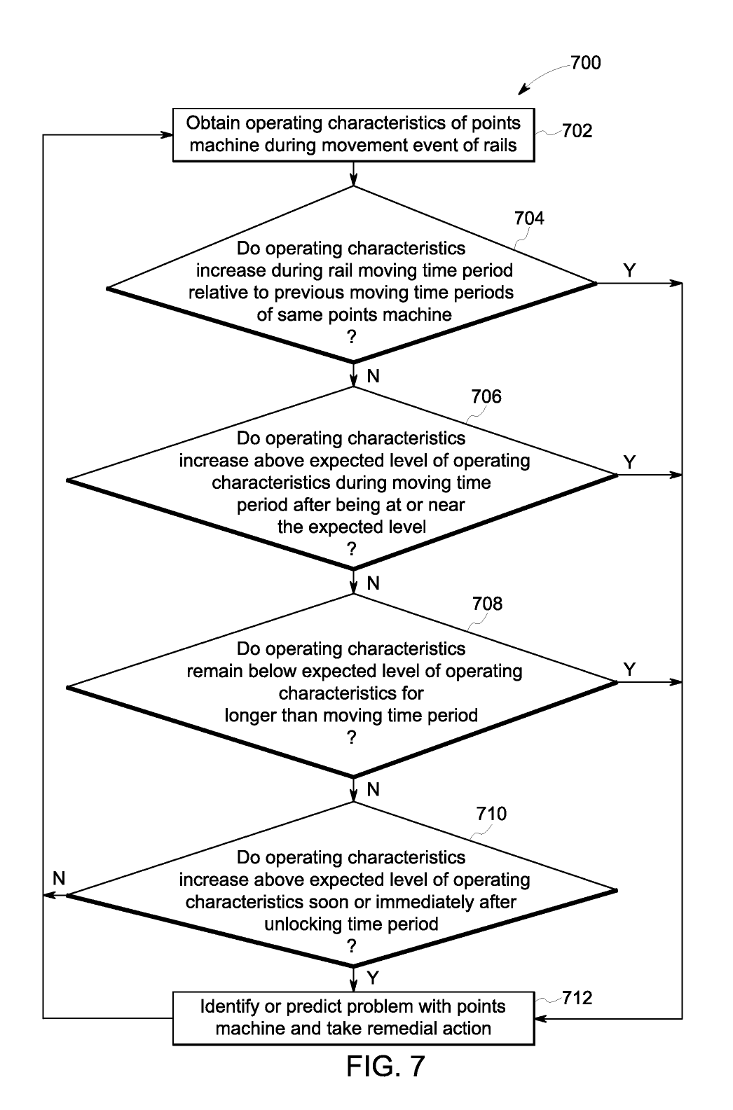

FIG. 7 illustrates a flowchart of a method 700 for monitoring a points machine in accordance with one embodiment of the inventive subject matter. The method 700 may be used by one or more embodiments of the monitoring system 100 to determine and/or predict potential problems with the points machine 102, such as deteriorating lubrication on switch plates 132, changing locations of the rails 112, 114 relative to the points machine 102, a foreign object between the rails 112, 114 that prevents the rails 112, 114 from moving to a locked position, a slipping clutch 124 of the points machine 102, frozen or stuck rails 112, 114, or another problem. Several of the examples described herein refer to examining the operating characteristics for a current movement event of the rails 114A, 112B. This can mean that the operating characteristics being examined are being analyzed during the same time period that the rails 114A, 112B are being moved by the points machine 102, or that the operating characteristics being examined were obtained during a previous movement event and are being analyzed after the previous movement event has completed.

At 702, operating characteristics of the points machine are monitored during a movement event that seeks to move the rails 114A, 112B toward or away from the rails 112A, 114B. The operating characteristics can include electric current that is demanded by a motor of the actuator 120 to move the rails 114A, 112B, or a fluid pressure, fluid flow, or the like, of hydraulic fluid or another fluid that is moved by the actuator 120 to move the rails 114A, 112B.

At 704, a determination is made as to whether the operating characteristics of the points machine being monitored increase during a current movement event relative to one or more previous movement events. For example, as described above in connection with the example of FIG. 3, the values of the operating characteristics during a current moving time period of the points machine under examination can be compared to the values of the operating characteristics (e.g., expected value, actual values, or another value) during the moving time period from one or previous movement events of the same points machine. Alternatively, the values of the operating characteristics during a current moving time period of the points machine under examination can be compared to the values of the operating characteristics during the moving time period from one or previous movement events of one or more other points machines.

If the values of the operating characteristics during the moving time period for a current movement event are larger than the values of the operating characteristics during the moving time periods one or more previous movement events, then the operating characteristics may be representative in an upward trend in the operating characteristics during the moving time period. This upward or increasing trend may indicate that the switch plates of the points machine need additional lubricant, that the rails have moved relative to the points machine, or another problem has arisen that is making it more difficult for the points machine to move the rails during the moving time period. Therefore, if such an upward trend is identified, one or more remedial actions may need to be taken. As a result, flow of the method 700 can continue to 712. Otherwise, flow of the method 700 may continue to 706.

At 706, a determination is made as to whether the operating characteristics of the points machine being monitored increase during the moving time period of a current movement event. For example, as described above in connection with the example of FIG. 4, the values of the operating characteristics during a current moving time period of the points machine under examination can initially be relatively steady, such as within the second plateau 216 of the waveform 400 during the time period 410 (all shown in FIG. 4). Then, the operating characteristics may increase, such as by increasing above the expected value 406 of the operating characteristics 200 in the second plateau 216, and/or above an average, median, or other calculation of the operating characteristics during the time period 410 prior to the increase.

If the values of the operating characteristics increase in this way during the moving time period for a current movement event, then the operating characteristics may indicate that a foreign object is interfering with movement of the rails 114A, 112B. As described above, a foreign object may be disposed between the rail 114A and the rail 112A and/or between the rail 112B and the rail 114A that is preventing the rails from moving to the locked position. Additionally or alternatively, this increase in the operating characteristics during the moving time period can otherwise indicate that the rail 114A and/or the rail 112B has otherwise become stuck in position before reaching the locked position. Therefore, if such an increase is identified during the moving time period, one or more remedial actions may need to be taken. As a result, flow of the method 700 can continue to 712. Otherwise, flow of the method 700 may continue to 708.

At 708, a determination is made as to whether the operating characteristics of the points machine being monitored are at or below an expected value for an extended period of time during the moving time period of a current movement event. For example, as described above in connection with the example of FIG. 6, the values of the operating characteristics during a current moving time period 222 of the points machine under examination can be less than the expected value 406 of the points machine 102 for a time period that is longer than the expected duration of the moving time period 222. The expected value 406 and/or the expected duration of the moving time period 222 can be designated values and/or can be calculated from historical values of the operating characteristics of the points machine 102 and/or one or more other points machines.

If the values of the operating characteristics remain below the expected value 406 for longer than expected (e.g., longer than the expected duration of the moving time period), then the operating characteristics may indicate that the clutch of the points machine is slipping. Therefore, one or more remedial actions may need to be taken. As a result, flow of the method 700 can continue to 712. Otherwise, flow of the method 700 may continue to 710.

At 710, a determination is made as to whether the operating characteristics of the points machine being monitored exceed an expected value very soon following the unlocking time period. For example, as described above in connection with the example of FIG. 5, the values of the operating characteristics can increase above the expected value 406 of the points machine 102 very soon after the unlocking time period 220. The expected value 406 and/or the expected duration of the unlocking time period 220 can be designated values and/or can be calculated from historical values of the operating characteristics of the points machine 102 and/or one or more other points machines.

If the values of the operating characteristics remain exceed the expected value 406 relatively soon after the unlocking time period 220, then the operating characteristics may indicate that the rails 114A and/or 114B are frozen or otherwise stuck in the locked position, and/or that a heating device of the points machine is not working properly. Therefore, one or more remedial actions may need to be taken. As a result, flow of the method 700 can continue to 712. Otherwise, flow of the method 700 may return to 702 so that additional operating characteristics of the points machine for the current or subsequent movement event can be examined.

At 712, one or more problems for the points machine may be identified or predicted, and/or one or more remedial actions may be taken. For example, if the operating characteristics demonstrate an upward trend in the second plateau 216 of the waveform over two or more movement events (e.g., as described in connection with FIG. 3), then a prediction may be made that the lubricant on the switch plates is deteriorating. A remedial action then may be taken that involves automatically issuing a signal that requests an operator travel to the points machine and examine the points machine and/or add lubricant to the switch plates.

As another example, if the operating characteristics increase above an expected value in the second plateau 216 of the waveform during a single movement event (e.g., as described in connection with FIG. 4), then it may be determined that a foreign object is stuck between the rail 114A and the rail 112A and/or between the rail 112B and the rail 114B. A remedial action then may be taken that involves automatically issuing a signal that requests an operator travel to the points machine and examine the points machine for any such foreign object.

As another example, if the operating characteristics remain below an expected value in the second plateau 216 of the waveform during a single movement event and/or for longer than expected (e.g., as described in connection with FIG. 6), then it may be determined that the clutch of the points machine is slipping. A remedial action then may be taken that involves automatically issuing a signal that requests an operator travel to the points machine and examine the points machine for any needed repairs or maintenance to the clutch or other part of the points machine.

As another example, if the operating characteristics rise above an expected value in the second plateau 216 of the waveform relatively soon after the unlocking time period during a single movement event (e.g., as described in connection with FIG. 5), then it may be determined that the rail 114A and/or the rail 112B is frozen or otherwise stuck in the locked position, and/or that a heater of the points machine is not functioning properly. A remedial action then may be taken that involves automatically issuing a signal that requests an operator travel to the points machine and examine the points machine and/or the heater for any needed repairs or maintenance. Flow of the method 700 can return to 702, where additional operating characteristics of the points machine are collected and examined.

In one embodiment, a method (e.g., for monitoring a points machine) includes obtaining operating characteristics of a points machine from a monitor operatively connected with the points machine. The operating characteristics are representative of operations of the points machine during a first movement event of rails at a switch. The first movement event moves at least a first rail toward or away from a second rail in order to change a path traveled by a vehicle traveling over the switch. The method also can include examining a waveform of the operating characteristics with a processor device in order to at least one of identify or predict a problem with the operations of the points machine. The waveform is examined by comparing the operating characteristics during the first movement event with at least one of the operating characteristics obtained during a previous, second movement event, an expected value of the operating characteristics during a first moving time period in which the at least a first rail is moved toward or away from the second rail by the points machine during the first movement event, and/or an expected duration of a second moving time period during which the at least a first rail is expected to at least one of move from an unlocked position away from the second rail to a locked position at or near the second rail or to move from the locked position to the unlocked position.

In one aspect, the operating characteristics that are obtained can include at least one of electric current supplied to a motor that operates to move the at least a first rail during the first movement event, a fluid pressure generated by the points machine to move the at least a first rail during the first movement event, and/or a fluid flow rate generated by the points machine to move the at least a first rail during the first movement event.

In one aspect, the waveform is examined by comparing values of the operating characteristics during the first moving time period with one or more historical values of the operating characteristics during historical moving time periods from one or more previous movement events of the points machine. The problem that is identified or predicted can include at least one of a deterioration of a lubricant on switch plates of the points machine or misalignment of the rails, where the problem can be identified or predicted responsive to one or more of the values of the operating characteristics of the first movement or the historical values of the historical moving time periods having an increasing trend over time.

In one aspect, the problem that is identified or predicted includes a foreign object disposed between the first rail and the second rail that is preventing the first rail from moving to the locked position. The problem can be identified or predicted responsive to the operating characteristics during the first movement event having values that are at the expected value for at least a first portion of the first moving time period and that increase above the expected value during a subsequent, second portion of the first moving time period.

In one aspect, the problem that is identified or predicted includes the first rail being frozen or stuck in position and unable to be moved by the points machine. The problem can be identified or predicted responsive to the operating characteristics during the first movement event having values that increase above the expected value subsequent to an unlocking time period during which the first rail is to be separated from a starting position of the first rail and remaining above the expected value for an extended time period that is longer than the expected duration of the second moving time period.

In one aspect, the problem that is identified or predicted includes a clutch of the points machine slipping. The problem can be identified or predicted responsive to the operating characteristics remaining below the expected value during the first moving time period.

In one aspect, at least one of the monitor or the processor device includes one or more hardware circuits or circuitry that at least one of include or are connected with one or more computer processors.

In another embodiment, a system (e.g., a points machine monitoring system) includes a monitor and a processor device. The monitor is configured to measure operating characteristics of a points machine. The operating characteristics are representative of operations of the points machine during a first movement event of rails at a switch. The first movement event moves at least a first rail toward or away from a second rail in order to change a path traveled by a vehicle traveling over the switch. The processor device is configured to examine a waveform of the operating characteristics in order to at least one of identify or predict a problem with the operations of the points machine. The processor device also is configured to examine the waveform by comparing the operating characteristics during the first movement event with at least one of the operating characteristics obtained during a previous, second movement event, an expected value of the operating characteristics during a first moving time period in which the at least a first rail is moved toward or away from the second rail by the points machine during the first movement event, and/or an expected duration of a second moving time period during which the at least a first rail is expected to at least one of move from an unlocked position away from the second rail to a locked position at or near the second rail or to move from the locked position to the unlocked position.

In one aspect, the monitor is configured to obtain and the processor device is configured to examine at least one of electric current supplied to a motor that operates to move the at least a first rail during the first movement event, a fluid pressure generated by the points machine to move the at least a first rail during the first movement event, and/or a fluid flow rate generated by the points machine to move the at least a first rail during the first movement event as the operating characteristics.

In one aspect, the processor device is configured to examine the waveform by comparing values of the operating characteristics during the first moving time period with one or more historical values of the operating characteristics during historical moving time periods from one or more previous movement events of the points machine. The processor device also can be configured to identify or predict the problem as one or more of a deterioration of a lubricant on switch plates of the points machine or a misalignment of the rails, where the problem is identified or predicted responsive to one or more of the values of the operating characteristics of the first movement or the historical values of the historical moving time periods having an increasing trend over time.

In one aspect, the processor device is configured to identify or predict the problem as a foreign object disposed between the first rail and the second rail that is preventing the first rail from moving to the locked position responsive to determining that the operating characteristics during the first movement event have values that are at the expected value for at least a first portion of the first moving time period and that increase above the expected value during a subsequent, second portion of the first moving time period.

In one aspect, the processor device is configured to identify or predict the problem as the first rail being frozen or stuck in position and unable to be moved by the points machine responsive to determining that the operating characteristics during the first movement event have values that increase above the expected value subsequent to an unlocking time period during which the first rail is to be separated from a starting position of the first rail and remaining above the expected value for an extended time period that is longer than the expected duration of the second moving time period.

In one aspect, the processor device is configured to identify or predict the problem as a clutch of the points machine slipping responsive to the operating characteristics remaining below the expected value during the first moving time period.

In one aspect, at least one of the monitor or the processor device includes one or more hardware circuits or circuitry that at least one of include or are connected with one or more computer processors.

In another embodiment, another method (e.g., for monitoring a points machine) includes measuring operating characteristics of a points machine when the points machine is activated to attempt to move first and second rails of a switch toward or away from a third rail to change a path traversed by a vehicle traveling over the switch. The operating characteristics include at least one of an electric current supplied to a motor of the points machine that generates movement to move the first and second rails, a fluid pressure generated by the points machine to move the first and second rails, and/or a rate of fluid flow generated by the points machine to move the first and second rails. The method also includes comparing the operating characteristics of the points machine with historical values of the operating characteristics that previously were obtained during one or more previous attempts by the points machine to move the first and second rails of the switch, the operating characteristics compared with the historical values in order to identify one or more differences. The method also includes at least one of identifying or predicting a problem with the points machine based on the one or more differences that are identified, the problem including at least one of a deterioration of a lubricant on switch plates of the points machine, a misalignment of at least one of the first rail or the second rail, at least one of the first rail or second rail being stuck in position, a clutch of the points machine slipping, and/or a foreign object stuck between at least one of the first rail or the second rail and one or more other rails.

In one aspect, the problem is identified or predicted as at least one of the deterioration of the lubricant or the misalignment of at least one of the first rail or the second rail responsive to the one or more differences representing an increasing trend in the operating characteristics during a moving time period in which the first and second rails are moved.

In one aspect, the problem is identified or predicted as the foreign object stuck between at least one of the first rail or the second rail and one or more other rails responsive to the operating characteristics having values that are at an expected value for at least a first portion of a moving time period during which the first and second rails are moved and that increase above the expected value during a subsequent, second portion of the moving time period.

In one aspect, the problem is identified or predicted as at least one of the first rail or second rail being stuck in position responsive to the operating characteristics having values that increase above an expected value subsequent to an unlocking time period during which the first rail is to be separated from a starting position of the first rail and remaining above the expected value for an extended time period that is longer than an expected duration, the expected value and the expected duration calculated from the historical values of the operating characteristics.

In one aspect, the problem is identified or predicted as the clutch of the points machine slipping responsive to the operating characteristics remaining below an expected value during a moving time period during which the first and second rails are moved, the expected value calculated from the historical values of the operating characteristics.

In one aspect, at least one of measuring or comparing the operating characteristics is performed by one or more hardware circuits or circuitry that at least one of include or are connected with one or more computer processors.

It is to be understood that the above description is intended to be illustrative, and not restrictive. For example, the above-described embodiments (and/or aspects thereof) may be used in combination with each other. In addition, many modifications may be made to adapt a particular situation or material to the teachings of the inventive subject matter without departing from its scope. While the dimensions and types of materials described herein are intended to define the parameters of the inventive subject matter, they are by no means limiting and are exemplary embodiments. Many other embodiments will be apparent to one of ordinary skill in the art upon reviewing the above description. The scope of the inventive subject matter should, therefore, be determined with reference to the appended claims, along with the full scope of equivalents to which such claims are entitled. In the appended claims, the terms “including” and “in which” are used as the plain-English equivalents of the respective terms “comprising” and “wherein.” Moreover, in the following claims, the terms “first,” “second,” and “third,” etc. are used merely as labels, and are not intended to impose numerical requirements on their objects. Further, the limitations of the following claims are not written in means-plus-function format and are not intended to be interpreted based on 35 U.S.C. §112(f), unless and until such claim limitations expressly use the phrase “means for” followed by a statement of function void of further structure.

This written description uses examples to disclose several embodiments of the inventive subject matter and also to enable one of ordinary skill in the art to practice the embodiments of inventive subject matter, including making and using any devices or systems and performing any incorporated methods. The patentable scope of the inventive subject matter is defined by the claims, and may include other examples that occur to one of ordinary skill in the art. Such other examples are intended to be within the scope of the claims if they have structural elements that do not differ from the literal language of the claims, or if they include equivalent structural elements with insubstantial differences from the literal languages of the claims.

The foregoing description of certain embodiments of the present inventive subject matter will be better understood when read in conjunction with the appended drawings. To the extent that the figures illustrate diagrams of the functional blocks of various embodiments, the functional blocks are not necessarily indicative of the division between hardware circuitry. Thus, for example, one or more of the functional blocks (for example, processors or memories) may be implemented in a single piece of hardware (for example, a general purpose signal processor, microcontroller, random access memory, hard disk, and the like). Similarly, the programs may be stand-alone programs, may be incorporated as subroutines in an operating system, may be functions in an installed software package, and the like. The various embodiments are not limited to the arrangements and instrumentality shown in the drawings.

As used herein, an element or step recited in the singular and proceeded with the word “a” or “an” should be understood as not excluding plural of said elements or steps, unless such exclusion is explicitly stated. Furthermore, references to “one embodiment” of the present inventive subject matter are not intended to be interpreted as excluding the existence of additional embodiments that also incorporate the recited features. Moreover, unless explicitly stated to the contrary, embodiments “comprising,” “including,” or “having” an element or a plurality of elements having a particular property may include additional such elements not having that property.

1. A method comprising:
obtaining operating characteristics of a points machine from a monitor operatively connected with the points machine, the operating characteristics representative of operations of the points machine during a first movement event of rails at a switch, the first movement event moving at least a first rail toward or away from a second rail in order to change a path traveled by a vehicle traveling over the switch; and
examining a waveform of the operating characteristics with a processor device in order to at least one of identify or predict a problem with the operations of the points machine,
wherein the waveform is examined by comparing the operating characteristics during the first movement event with at least one of:
the operating characteristics obtained during a previous, second movement event;
an expected value of the operating characteristics during a first moving time period in which the at least a first rail is moved toward or away from the second rail by the points machine during the first movement event; or
an expected duration of a second moving time period during which the at least a first rail is expected to at least one of move from an unlocked position away from the second rail to a locked position at or near the second rail or to move from the locked position to the unlocked position.

2. The method of claim 1, wherein the operating characteristics that are obtained include at least one of electric current supplied to a motor that operates to move the at least a first rail during the first movement event, a fluid pressure generated by the points machine to move the at least a first rail during the first movement event, or a fluid flow rate generated by the points machine to move the at least a first rail during the first movement event.

3. The method of claim 1, wherein the waveform is examined by comparing values of the operating characteristics during the first moving time period with one or more historical values of the operating characteristics during historical moving time periods from one or more previous movement events of the points machine, and
wherein the problem that is identified or predicted includes at least one of a deterioration of a lubricant on switch plates of the points machine or misalignment of the rails, the problem identified or predicted responsive to one or more of the values of the operating characteristics of the first movement or the historical values of the historical moving time periods having an increasing trend over time.

4. The method of claim 1, wherein the problem that is identified or predicted includes a foreign object disposed between the first rail and the second rail that is preventing the first rail from moving to the locked position, and
wherein the problem is identified or predicted responsive to the operating characteristics during the first movement event having values that are at the expected value for at least a first portion of the first moving time period and that increase above the expected value during a subsequent, second portion of the first moving time period.

5. The method of claim 1, wherein the problem that is identified or predicted includes the first rail being frozen or stuck in position and unable to be moved by the points machine, and
wherein the problem is identified or predicted responsive to the operating characteristics during the first movement event having values that increase above the expected value subsequent to an unlocking time period during which the first rail is to be separated from a starting position of the first rail and remaining above the expected value for an extended time period that is longer than the expected duration of the second moving time period.

6. The method of claim 1, wherein the problem that is identified or predicted includes a clutch of the points machine slipping, and
wherein the problem is identified or predicted responsive to the operating characteristics remaining below the expected value during the first moving time period.

7. The method of claim 1, wherein at least one of the monitor or the processor device includes one or more hardware circuits or circuitry that at least one of include or are connected with one or more computer processors.

8. A system comprising:
a monitor configured to measure operating characteristics of a points machine, the operating characteristics representative of operations of the points machine during a first movement event of rails at a switch, the first movement event moving at least a first rail toward or away from a second rail in order to change a path traveled by a vehicle traveling over the switch; and
a processor device configured to examine a waveform of the operating characteristics in order to at least one of identify or predict a problem with the operations of the points machine,
wherein the processor device is configured to examine the waveform by comparing the operating characteristics during the first movement event with at least one of:
the operating characteristics obtained during a previous, second movement event;
an expected value of the operating characteristics during a first moving time period in which the at least a first rail is moved toward or away from the second rail by the points machine during the first movement event; or
an expected duration of a second moving time period during which the at least a first rail is expected to at least one of move from an unlocked position away from the second rail to a locked position at or near the second rail or to move from the locked position to the unlocked position.

9. The system of claim 8, wherein the monitor is configured to obtain and the processor device is configured to examine at least one of electric current supplied to a motor that operates to move the at least a first rail during the first movement event, a fluid pressure generated by the points machine to move the at least a first rail during the first movement event, or a fluid flow rate generated by the points machine to move the at least a first rail during the first movement event as the operating characteristics.

10. The system of claim 8, wherein the processor device is configured to examine the waveform by comparing values of the operating characteristics during the first moving time period with one or more historical values of the operating characteristics during historical moving time periods from one or more previous movement events of the points machine, and
wherein the processor device is configured to identify or predict the problem as one or more of a deterioration of a lubricant on switch plates of the points machine or a misalignment of the rails, the problem identified or predicted responsive to one or more of the values of the operating characteristics of the first movement or the historical values of the historical moving time periods having an increasing trend over time.

11. The system of claim 8, wherein the processor device is configured to identify or predict the problem as a foreign object disposed between the first rail and the second rail that is preventing the first rail from moving to the locked position responsive to determining that the operating characteristics during the first movement event have values that are at the expected value for at least a first portion of the first moving time period and that increase above the expected value during a subsequent, second portion of the first moving time period.

12. The system of claim 8, wherein the processor device is configured to identify or predict the problem as the first rail being frozen or stuck in position and unable to be moved by the points machine responsive to determining that the operating characteristics during the first movement event have values that increase above the expected value subsequent to an unlocking time period during which the first rail is to be separated from a starting position of the first rail and remaining above the expected value for an extended time period that is longer than the expected duration of the second moving time period.

13. The system of claim 8, wherein the processor device is configured to identify or predict the problem as a clutch of the points machine slipping responsive to the operating characteristics remaining below the expected value during the first moving time period.

14. The system of claim 8, wherein at least one of the monitor or the processor device includes one or more hardware circuits or circuitry that at least one of include or are connected with one or more computer processors.

15. A method comprising:
measuring operating characteristics of a points machine when the points machine is activated to attempt to move first and second rails of a switch toward or away from a third rail to change a path traversed by a vehicle traveling over the switch, the operating characteristics including at least one of an electric current supplied to a motor of the points machine that generates movement to move the first and second rails, a fluid pressure generated by the points machine to move the first and second rails, or a rate of fluid flow generated by the points machine to move the first and second rails;
comparing the operating characteristics of the points machine with historical values of the operating characteristics that previously were obtained during one or more previous attempts by the points machine to move the first and second rails of the switch, the operating characteristics compared with the historical values in order to identify one or more differences; and
at least one of identifying or predicting a problem with the points machine based on the one or more differences that are identified, the problem including at least one of a deterioration of a lubricant on switch plates of the points machine, a misalignment of at least one of the first rail or the second rail, at least one of the first rail or second rail being stuck in position, a clutch of the points machine slipping, or a foreign object stuck between at least one of the first rail or the second rail and one or more other rails.

16. The method of claim 15, wherein the problem is identified or predicted as at least one of the deterioration of the lubricant or the misalignment of at least one of the first rail or the second rail responsive to the one or more differences representing an increasing trend in the operating characteristics during a moving time period in which the first and second rails are moved.

17. The method of claim 15, wherein the problem is identified or predicted as the foreign object stuck between at least one of the first rail or the second rail and one or more other rails responsive to the operating characteristics having values that are at an expected value for at least a first portion of a moving time period during which the first and second rails are moved and that increase above the expected value during a subsequent, second portion of the moving time period.

18. The method of claim 15, wherein the problem is identified or predicted as at least one of the first rail or second rail being stuck in position responsive to the operating characteristics having values that increase above an expected value subsequent to an unlocking time period during which the first rail is to be separated from a starting position of the first rail and remaining above the expected value for an extended time period that is longer than an expected duration, the expected value and the expected duration calculated from the historical values of the operating characteristics.

19. The method of claim 15, wherein the problem is identified or predicted as the clutch of the points machine slipping responsive to the operating characteristics remaining below an expected value during a moving time period during which the first and second rails are moved, the expected value calculated from the historical values of the operating characteristics.

20. The method of claim 15, wherein at least one of measuring or comparing the operating characteristics is performed by one or more hardware circuits or circuitry that at least one of include or are connected with one or more computer processors.
